(19) United States
(12) Patent Application Publication
(10) Pub. No.: US 2024/0213388 A1
(43) Pub. Date: Jun. 27, 2024

(54) MULTI-JUNCTION SOLAR CELL AND METHOD FOR MANUFACTURING THE SAME

(71) Applicant: KOREA UNIVERSITY RESEARCH AND BUSINESS FOUNDATION, Seoul (KR)

(72) Inventors: Hae-Seok LEE, Seoul (KR); Donghwan KIM, Yangpyeong-gun (KR); Yoonmook KANG, Seoul (KR); Dowon PYUN, Seoul (KR); Dongjin CHOI, Seoul (KR); Jae-Keun HWANG, Seoul (KR); Dongkyun KANG, Yangsan-si (KR); Solhee LEE, Seoul (KR); Hoyoung SONG, Seoul (KR); Seok-Hyun JEONG, Seoul (KR); MyeongSeob SIM, Seoul (KR)

(21) Appl. No.: 18/388,231

(22) Filed: Nov. 9, 2023

(30) Foreign Application Priority Data
Dec. 27, 2022 (KR) 10-2022-0185140

(51) Int. Cl. H01L 31/0725; H01L 31/0224; H01L 31/028; H01L 31/18

(52) U.S. Cl. CPC H01L 31/0725; H01L 31/022491; H01L 31/028; H01L 31/1884

(57) ABSTRACT

Disclosed is a method for manufacturing a multi-junction solar cell including forming a lower cell, depositing a metal thin film layer on the lower cell, heat-treating the metal thin film layer to form a recombination layer and an intermediate charge transport layer, and forming an upper cell on the intermediate charge transport layer. After depositing a metal thin film on top of the lower cell, the deposited metal thin film is heat-treated at a high temperature, so that metal atoms in the metal thin film diffuse to the top of the lower cell to form the recombination layer of silicide at an interface between the metal thin film and the lower cell, and at the same time, oxygen atoms diffuse into the metal thin film to form metal oxide (the charge transport layer) at a surface of the metal thin film.

### CROSS-REFERENCE TO RELATED APPLICATIONS

This application claims priority under 35 U.S.C. § 119 to Korean Patent Application No. 10-2022-0185140 filed on Dec. 27, 2022, in the Korean Intellectual Property Office, the disclosures of which are incorporated by reference herein in their entireties.

### BACKGROUND

Embodiments of the present disclosure described herein relate to a multi-junction solar cell and a method for manufacturing the same.

The present disclosure is derived from research conducted as part of the Ministry of Economy and Finance's (Science and Engineering) (Type 1-1) mid-sized research (project number: 2023R1A2C100712811, research management agency: National Research Foundation of Korea, research project name: a development of a TCO-free recombination layer nano material source technology to realize 30% ultra-high efficiency tandem solar cell, host organization: Korea University Industry-Academic Cooperation Foundation, research period: 2023 Mar. 1.˜2024 Feb. 29, contribution rate: ½).

In addition, the present disclosure is derived from research conducted as part of the Ministry of Economy and Finance's development of a step-up carbon neutral technology (project number: 2022M3J1A1063226, research management agency: National Research Foundation of Korea, research project name: a development of a perovskite solar cell element technology for an ultra-high efficiency tandem (multi-junction), host organization: Korea University Industry-Academic Cooperation Foundation, research period: 2022 May 24.˜2023 Jan. 23, contribution rate: ½).

There is no property interest of the Korean government in any aspect of this invention.

A problem of global warming is worsening worldwide. To overcome the same, in 2015, the world signed the Paris Agreement on climate change whose objective is to hold the increase in the global average temperature to well below 2 degrees. Therefore, to prevent the global warming, it is essential to reduce a use of existing fossil energy and develop new and renewable energy that may replace the fossil energy.

The new and renewable energy is energy that is used by recycling the existing fossil fuel or converting the fossil fuel into renewable energy, and includes solar energy, geothermal energy, ocean energy, bioenergy, and the like.

Among these, the solar energy and solar light are pollution-free, infinite, and usable anywhere on Earth. A solar cell was developed to utilize the solar energy and the solar light, and is an element that converts light energy generated from the sun into electrical energy using a photovoltaic effect.

Various organic, inorganic, and organic-inorganic hybrid solar cells have been developed, but a use of power generated using the solar cell in a total power production is still at a low level. This is because a power generation cost of the solar cell is higher than a cost of general electricity produced using the fossil fuel. A solar cell efficiency is an important factor in determining the power generation cost of the solar cell, and improving the solar cell efficiency is important to increase price competitiveness.

Recently, a silicon solar cell with the efficiency equal to or greater than 26% has been successfully developed and is steadily growing, but has a limitation in the efficiency improvement because a theoretical efficiency that may be achieved using the silicon solar cell of a current structure is 29.4%.

The currently commercialized solar cell structure is a single-junction structure, which limits an overall use of light from the sun. To overcome such problem, it is necessary to implement a multi-junction solar cell that uses a solar light spectrum more efficiently by stacking the solar cells with a band gap that may absorb a specific wavelength range. In this regard, the theoretical efficiency limit increases up to 87%.

In one example, research on a perovskite solar cell began in 2009 when Professor Miyasaka's team in Japan applied methylammonium lead iodide, which is an organic-inorganic composite material, to an existing dye-sensitized solar cell. An efficiency thereof, which was only 3.8% at the time, has increased rapidly and recently reached 25%.

Until the development of the perovskite solar cell, there were no high-efficiency solar cells with a high bandgap that may be applied as an upper cell of a multi-junction, except for a group III-V solar cell. However, with the development of the high-efficiency perovskite solar cell, research is being actively conducted to increase the efficiency using a tandem structure, which is a double-junction structure with a solar cell developed in advance.

The multi-junction solar cell may be implemented using the existing solar cell as a lower cell and the perovskite solar cell as the upper cell.

In the case of multi-junction solar cell, one solar cell is constituted by connecting the upper cell and the lower cell in series to each other. To efficiently utilize characteristics of each cell, a portion where the two layers are connected to each other is important. This is a layer where holes generated above and electrons generated below, or electrons generated above and holes generated below are recombined with each other, and is also referred to as a recombination layer.

In other words, the recombination layer is very important because the upper cell and the lower cell of the multi-junction solar cell are electrically connected in series with each other.

The existing multi-junction solar cell will be described with reference to FIG. 1.

The lower cell is formed by sequentially depositing a lower electrode, a reflection layer, a passivation layer, a lower first charge transport layer, a lower absorption layer, and an emitter layer (or a lower second charge transport layer).

Then, the recombination layer is coupled onto the emitter layer. In this regard, a transparent conductive oxide (TCO) may be used as the recombination layer.

In addition, the TCO is made of a transparent conductive material such as ITO, IZO, AZO, and GZO, and is deposited via sputtering.

Then, the upper cell is deposited on the recombination layer.

The upper cell is formed by sequentially depositing an intermediate charge transport layer, an upper absorption layer, an upper second charge transport layer, a buffer layer, a transparent layer, and an upper electrode on the recombination layer.

In this regard, the intermediate charge transport layer may be an electron/hole transport layer made of an oxide (TiO₂, SnO₂, ZnO₂/NiO_{X}, CuO₂, MoO_{X}, and the like) or an organic material (C60, BCP, PCBM/spiro-OMeTAD and the like).

However, in the case of multi-junction solar cell using the TCO as the recombination layer, the characteristics of the lower cell were deteriorated by a plasma damage occurring during the sputtering process.

In addition, in a case of indium (In), a main component of the ITO, as one of rare earth materials with limited reserves, a use of the indium may be problematic in a future expansion of a solar light market, such as an area size increase, commercialization, and the like of the solar cell.

Accordingly, ways to replace the ITO to solve the above-mentioned problems and maximize a photoelectric conversion efficiency of the multi-junction solar cell are being studied.

### SUMMARY

Embodiments of the present disclosure provide a multi-junction solar cell and a method for manufacturing the same that, after depositing a metal thin film on top of a lower cell, heat-treats the deposited metal thin film at a high temperature, so that metal atoms in the metal thin film diffuse to the top of the lower cell to form the recombination layer of silicide at an interface between the metal thin film and the lower cell, and at the same time, oxygen atoms diffuse into the metal thin film to form metal oxide (a charge transport layer) at a surface of the metal thin film.

Embodiments of the present disclosure provide a multi-junction solar cell and a method for manufacturing the same that may form a new recombination layer that may replace a TCO used as a recombination layer in an existing multi-junction solar cell and use metal oxide formed at the same time as a charge transport layer to reduce process steps when manufacturing an upper cell.

The technical problems to be solved by the present disclosure are not limited to the aforementioned problems, and any other technical problems not mentioned herein will be clearly understood from the following description by those skilled in the art to which the present disclosure pertains.

According to an embodiment, a method for manufacturing a multi-junction solar cell includes forming a lower cell, depositing a metal thin film layer on the lower cell, heat-treating the metal thin film layer to form a recombination layer and an intermediate charge transport layer, and forming an upper cell on the intermediate charge transport layer.

In addition, the metal thin film layer may contain one of Ti, Ni, and Mo.

In addition, the lower cell may be formed by sequentially depositing a lower electrode, a lower absorption layer, and an emitter layer, and the lower absorption layer may be a silicon substrate.

In addition, the metal thin film layer may contain one of Ni and Mo when the emitter layer is of an n-type, and the metal thin film layer may contain Ti when the emitter layer is of a p-type.

In addition, the recombination layer formed by the heat-treatment of the metal thin film layer may be made of one silicide among TiSi₂, NiSi₂, and MoSi₂.

In addition, in the heat-treating of the metal thin film layer, the intermediate charge transport layer formed by the heat-treatment of the metal thin film layer may be made of one metal oxide among TiO₂, NiO₂, and MoO_{X}.

In addition, the heat-treating of the metal thin film layer may include simultaneously forming the recombination layer and the intermediate charge transport layer via the heat-treatment in an oxygen atmosphere.

According to an embodiment, a multi-junction solar cell includes a lower cell including a lower electrode, a lower absorption layer, and an emitter layer deposited sequentially, a recombination layer disposed on the emitter layer, an intermediate charge transport layer disposed on the recombination layer, and an upper cell disposed on the intermediate charge transport layer and including an upper absorption layer and an upper electrode deposited sequentially.

In addition, a metal thin film layer may be deposited on the emitter layer and then heat-treated, metal atoms of the metal thin film layer may diffuse into the emitter layer to form the recombination layer made of silicide, and, at a surface of the metal thin film layer, oxygen atoms may diffuse into a metal thin film to form the intermediate charge transport layer made of metal oxide.

In addition, the lower absorption layer may include a silicon substrate, and the upper absorption layer may contain perovskite.

In addition, the heat-treatment may be performed in an oxygen atmosphere, so that the recombination layer made of the silicide and the intermediate charge transport layer made of the metal oxide are formed simultaneously.

According to the embodiments of the present disclosure, after depositing the metal thin film on top of the lower cell, the deposited metal thin film is heat-treated at the high temperature, so that the metal atoms in the metal thin film diffuse to the top of the lower cell to form the recombination layer of the silicide at the interface between the metal thin film and the lower cell, and at the same time, the oxygen atoms diffuse into the metal thin film to form the metal oxide (the charge transport layer) at the surface of the metal thin film.

In addition, according to the embodiments of the present disclosure, the multi-junction solar cell may be manufactured as the new recombination layer that may replace the TCO used as the recombination layer in the existing multi-junction solar cell is formed and the metal oxide formed at the same time is used as the charge transport layer to reduce the process steps when manufacturing the upper cell.

The effects that may be obtained from the present disclosure are not limited to the aforementioned effects, and any other effects not mentioned herein will be clearly understood from the following description by those skilled in the art to which the present disclosure pertains.

### BRIEF DESCRIPTION OF THE FIGURES

The above and other objects and features of the present disclosure will become apparent by describing in detail embodiments thereof with reference to the accompanying drawings.

FIG. 1 is a structural diagram showing an existing multi-junction solar cell.

FIG. 2 is a structural diagram showing a multi-junction solar cell according to an embodiment of the present disclosure.

FIGS. 3A to 3D are a flowchart showing a method for manufacturing a multi-junction solar cell according to an embodiment of the present disclosure.

FIGS. 4A to 4C are schematic diagrams showing a state in which silicide and metal oxide are formed.

FIG. 5 is a schematic diagram showing heat-treatment of a titanium (Ti) metal thin film layer.

FIG. 6 is a schematic diagram showing heat-treatment of a nickel (Ni) metal thin film layer.

FIG. 7 is a photograph taken with a scanning electron microscope and a transmission electron microscope according to Experimental Example 1.

FIG. 8 is a graph showing voltage-current characteristics according to Experimental Example 2.

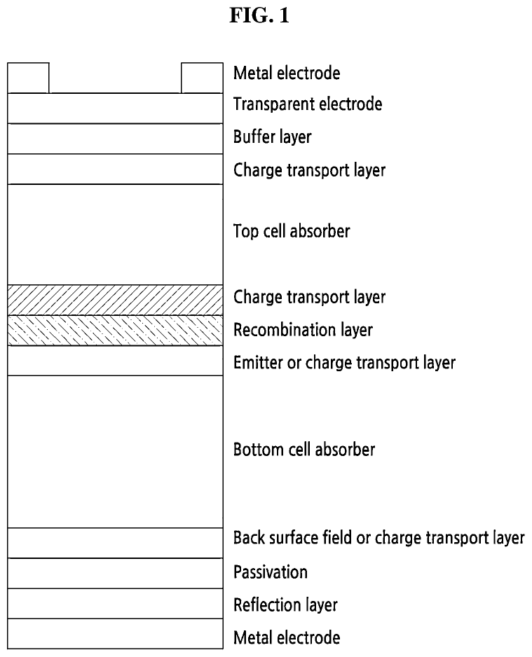

### DETAILED DESCRIPTION

Hereinafter, embodiments of the present disclosure will be described in more detail with reference to the attached drawings. The embodiments of the present disclosure may be modified in various forms, and the scope of the present disclosure should not be construed as being limited to the embodiments below. The present embodiment is provided to more fully describe the present disclosure to a person with average knowledge in the art. Therefore, shapes of components in the drawings are exaggerated to emphasize clearer description.

A composition of the present disclosure to clarify the solution to the problem that the present disclosure is to solve is described in detail with reference to the accompanying drawings based on preferred embodiments of the present disclosure. When assigning reference numerals to components in a drawing, the same reference numeral is assigned to the same component even when the component is in a different drawing. It is stated in advance that components of other drawings may be cited when necessary when describing the relevant drawing.

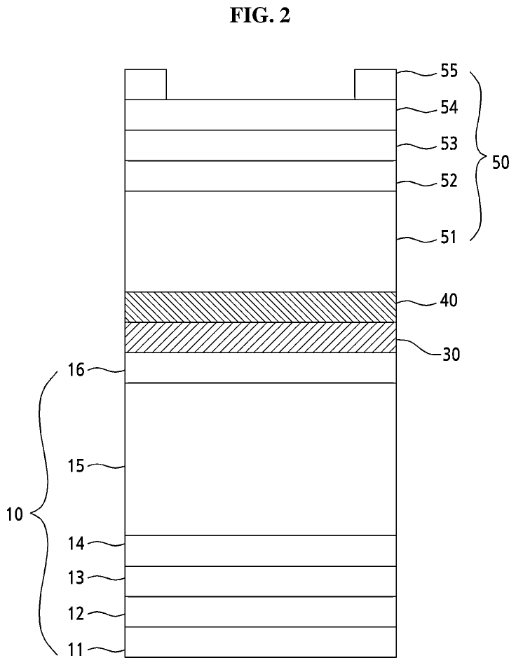

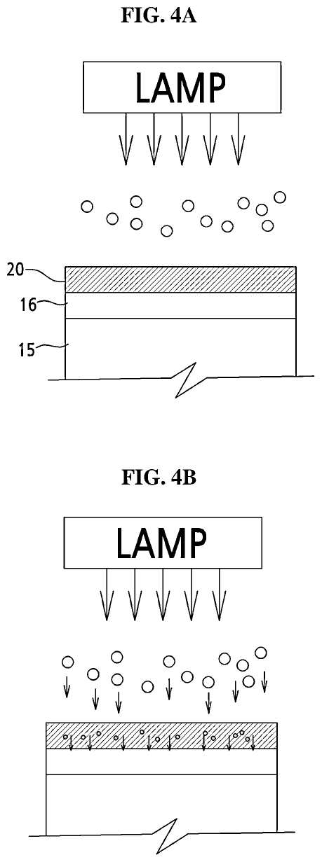

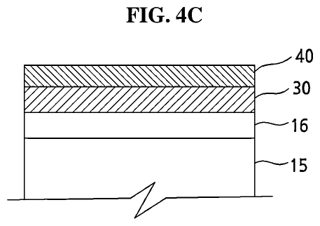

Referring to FIGS. 2 to 4C, a multi-junction solar cell according to one embodiment of the present disclosure may include a lower cell 10, a recombination layer 30, an intermediate charge transport layer 40, and an upper cell 50.

First, the lower cell 10 may be formed by sequentially depositing a lower absorption layer 15 and an emitter layer 16.

Specifically, the lower cell 10 may be formed by sequentially depositing a lower electrode 11, a reflection layer 12, a passivation layer 13, a lower first charge transport layer 14, the lower absorption layer 15, and the emitter layer 16, but the present disclosure may not be limited thereto. In this regard, the emitter layer 16 may be a lower second charge transport layer.

In this regard, the lower first charge transport layer 14 and the lower second charge transport layer may transport electrons or holes.

Additionally, the emitter layer 16 may be of an n-type or a p-type.

Additionally, the lower absorption layer 15 may be a silicon substrate. This is to allow, during heat-treatment of a metal thin film layer 20 to be described later, metal atoms of the metal thin film layer 20 to diffuse into the lower absorption layer 15 and form the recombination layer 30 to be described later.

The lower cell 10 described above may be in a form of a silicon solar cell without a front electrode.

The recombination layer 30 is formed as described above by depositing the metal thin film layer 20 on the emitter layer 16 and heat-treating the layer 20. In this regard, the recombination layer 30 may be made of one silicide among TiSi₂, NiSi₂, and MoSi₂.

In addition, when the metal thin film layer 20 is heat-treated, the silicide is formed, and at the same time, oxygen atoms diffuse into the metal thin film layer 20, thereby forming metal oxide on the metal thin film layer 20.

In this regard, the heat-treatment is performed in an oxygen atmosphere, so that the recombination layer 30 of the silicide and the intermediate charge transport layer 40 of the metal oxide may be formed simultaneously. Additionally, the heat-treatment may be performed at a high temperature equal to or higher than 400° C.

In this regard, the metal oxide may be formed as the intermediate charge transport layer 40, which is a charge transport layer or a hole transport layer, depending on whether the metal thin film layer 20 is of one of Ti, Ni, and Mo.

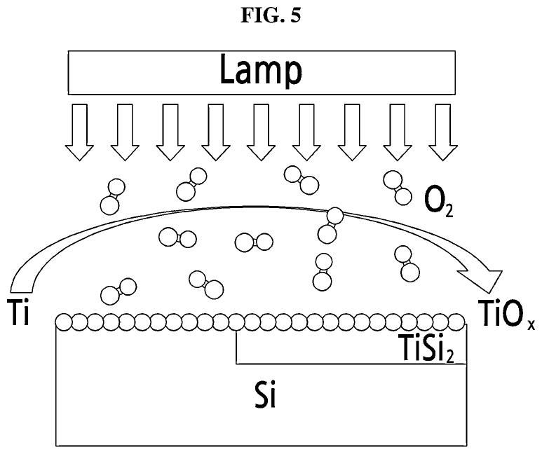

For example, as shown in FIG. 5, when the metal thin film layer 20 is of Ti, metal oxide of TiO₂ may be formed to serve as the electron transport layer. In this regard, it is preferable that the emitter layer 16 is of the p-type.

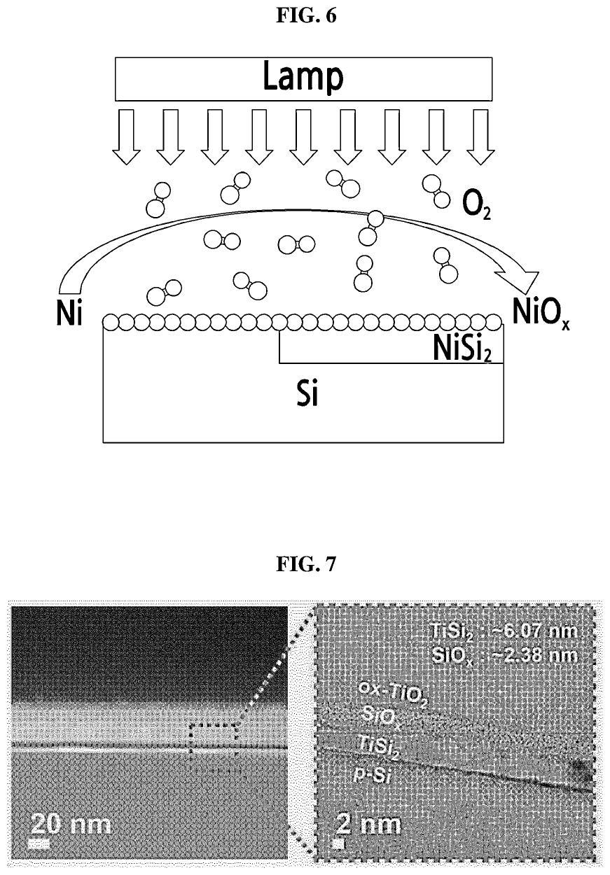

In addition, as shown in FIG. 6, when the metal thin film layer 20 is of Ni, metal oxide of NiO₂ may be formed, and when the metal thin film layer 20 is of Mo, MoO_{X} metal oxide may be formed to serve as the hole transport layer. In this regard, it is preferable that the emitter layer 16 is of the n-type.

Accordingly, the new recombination layer 30 that may replace a TCO may be formed. In particular, the TCO is made of a transparent conductive material such as ITO, IZO, AZO, and GZO, and is deposited via sputtering. However, the multi-junction solar cell in the present disclosure does not use the TCO, so that there is no plasma damage occurring during the sputtering process, thereby maintaining characteristics of the lower cell 10. In addition, because indium (In), a main component of the ITO of the TCO, is not required, the multi-junction solar cell may be easily utilized, such as increasing an area size of the solar cell.

In addition, because the metal oxide formed at the same time as the recombination layer 30 may be used as the electron transport layer or the hole transport layer, the metal oxide may be used as the intermediate charge transport layer 40, so that a process of depositing the electron transport layer or the hole transport layer may be omitted when manufacturing the upper cell 50.

The upper cell 50 may be formed by sequentially depositing an upper absorption layer 51 and an upper electrode 55 on the intermediate charge transport layer 40.

Specifically, the upper cell 50 may be formed by sequentially depositing the upper absorption layer 51, an upper charge transport layer 52, a buffer layer 53, a transparent layer 54, and the upper electrode 55 on the intermediate charge transport layer 40, but the present disclosure may not be limited thereto.

In this regard, the upper absorption layer 51 may be a perovskite layer, and the upper cell 50 may be formed in a form of a perovskite solar cell without a back electrode.

Each layer of the lower cell 10 and the upper cell 50 described above will be described, but the present disclosure is not limited thereto.

The lower electrode 11 may be at least one material selected among molybdenum (Mo), aluminum (Al), silver (Ag), gold (Au), platinum (Pt), copper (Cu), nickel (Ni), and carbon (C), or a metal alloy containing two or more of those materials.

In addition, the lower electrode 11 may perform a function of reflecting light incident from above such that the light does not escape to the outside.

The reflection layer 12 serves to increase a photoelectric conversion efficiency by increasing a path of the light incident from above.

The passivation layer 13 may be composed of a light-transmitting insulating film, and an oxide- and nitride-insulating film may be used.

The buffer layer 53 may serve as a boundary between the upper absorption layer 51 and the transparent layer 54, and cadmium sulfide (CdS) may be used therefor.

The transparent layer 54 may be formed as a transparent conductive layer using materials such as zinc oxide (ZnO), indium tin oxide (ITO), and aluminum-doped zinc oxide (AZO).

The upper electrode 55 may be at least one material selected among molybdenum (Mo), aluminum (Al), silver (Ag), gold (Au), platinum (Pt), copper (Cu), nickel (Ni), and carbon (C), or a metal alloy containing two or more of those materials.

In addition, when the charge transport layer is the hole transport layer, such hole transport layer may be PEDOT:PSS(poly(3,4-ethylenedioxythiophene):poly(styrenesulfonate)), polythiophenylenevinylene, polyvinylcarbazole, poly-p-phenylenevinylene, poly(3-hexylthiophene-2,5-diyl) (P3HT), poly[bis(4-phenyl)(2,4,6-trimethylphenyl)amine] (PTAA), 9′-spirobi[9H-fluorene]-2,2′,7,7′-tetramine (Spiro-MeOTAD), and derivatives thereof. However, the present disclosure may not be limited thereto, and various types of organic materials may be used. Additionally, molybdenum oxide, vanadium oxide, tungsten oxide, nickel oxide, and the like, which are p-type doped metal oxide semiconductors, may be used.

In addition, when the charge transport layer is the electron transport layer, such electron transport layer may be fullerene (C60, C70, and C80) or PCBM ([6,6]-phenyl-C61 butyric acid methyl ester) (PCBM (C60), PCBM(C70), and PCBM(C80)), which are fullerene derivatives. However, the present disclosure may not be limited thereto, and various types of organic materials may be used. Additionally, titanium oxide (TiOₓ), zinc oxide (ZnO), tin oxide (SnOₓ), and the like, which are n-type doped metal oxide semiconductors, may be used.

Hereinafter, a method for manufacturing a multi-junction solar cell according to the present disclosure will be described. In addition, while describing the method for manufacturing the multi-junction solar cell, the same configuration as the multi-junction solar cell described above will be omitted.

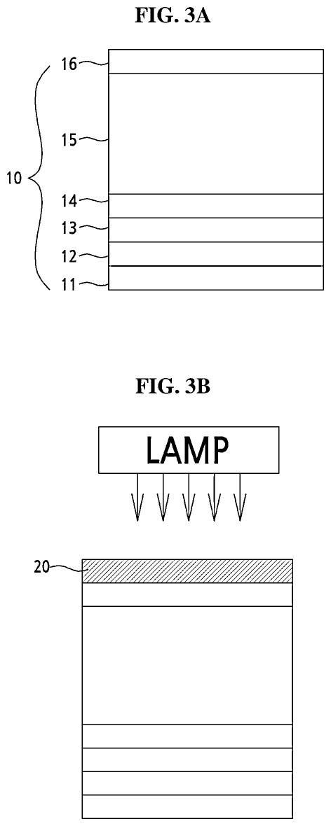

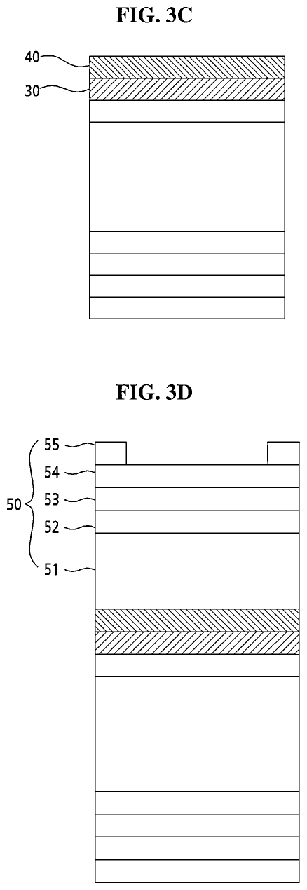

The method for manufacturing the multi-junction solar cell in the present disclosure may first form the lower cell 10, as shown in FIG. 3A.

In this regard, the lower cell 10 may be formed by sequentially depositing the lower electrode 11, the lower absorption layer 15, and the emitter layer 16, and the lower absorption layer 15 may be the silicon substrate.

Next, referring to FIG. 3B, the metal thin film layer 20 may be deposited on the lower cell 10.

In this regard, the metal thin film layer 20 may contain one of Ti, Ni, and Mo.

In particular, the metal thin film layer 20 may be one of Ni and Mo when the emitter layer 16 is of the n-type, and may be Ti when the emitter layer 16 is of the p-type.

Next, referring to FIG. 3C, the metal thin film layer 20 may be heat-treated to form the recombination layer 30 and the intermediate charge transport layer 40.

In this regard, the recombination layer 30 formed by the heat-treatment of the metal thin film layer 20 may be made of one silicide among TiSi₂, NiSi₂, and MoSi₂.

In addition, the intermediate charge transport layer 40, which is formed by the heat-treatment of the metal thin film layer 20, may be made of one metal oxide among TiO₂, NiO₂, and MoO_{X}, and may transport the electrons or the holes.

Additionally, when the metal thin film layer 20 is heat-treated to form the recombination layer 30 and the intermediate charge transport layer 40, the recombination layer 30 and the intermediate charge transport layer 40 may be formed simultaneously via the heat-treatment in the oxygen atmosphere.

Lastly, referring to FIG. 3D, the upper cell 50 may be formed on the intermediate charge transport layer 40.

Examples of the multi-junction solar cell manufactured by the above-described method for manufacturing the multi-junction solar cell will be described.

### EXAMPLES

The p-type emitter layer 16 is deposited on the silicon substrate and then the metal thin film layer 20 of Ti is deposited on the p-type emitter layer 16. Then, the Ti metal thin film layer 20 is heat-treated at the temperature equal to or higher than 400° C. using a lamp. As a result, the silicide and the metal oxide are formed.

### Experimental Example 1

As shown in FIG. 7, when viewing a cross-section of the manufactured multi-junction solar cell using a scanning electron microscope and a transmission electron microscope, it may be seen that a silicide of TiS₂ with a thickness of 6.07 nm and a charge transport layer of TiO₂ with a thickness of 2.38 nm are formed.

### Experimental Example 2

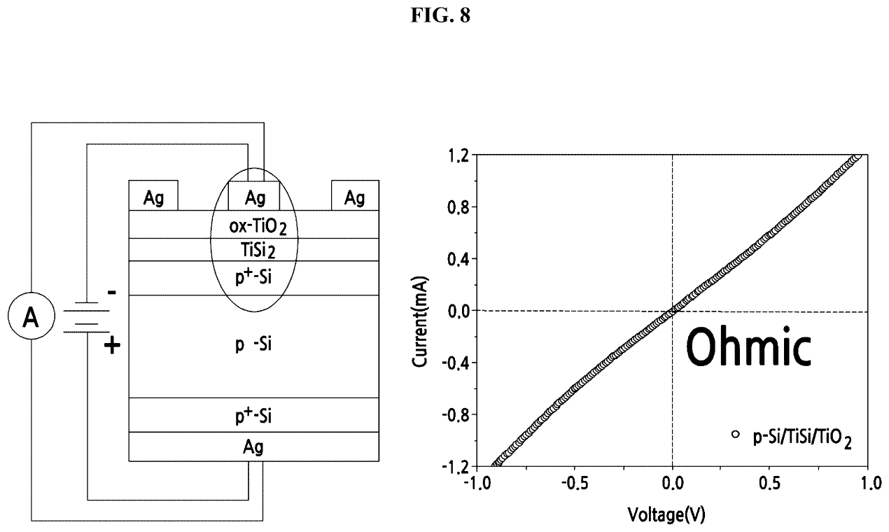

As shown in FIG. 8, excellent electrical characteristics at an interface resulted from the silicide may be identified from a current-voltage measurement graph of the multi-junction solar cell according to Example.

The above detailed description is illustrative of the present disclosure. Additionally, the foregoing describes the preferred embodiments of the present disclosure, and the present disclosure are able to be used in a variety of different combinations, modifications, and circumstances. That is, changes or modifications may be made within the scope of the concept of the present disclosure disclosed herein, within the scope equivalent to the described disclosure, and/or within the scope of technology or knowledge in the art. The described embodiment is to describe the best state for implementing the technical idea of the present disclosure, and various changes required for specific application fields and uses of the present disclosure are also possible. Accordingly, the above detailed description of the present disclosure is not intended to limit the present disclosure to the disclosed embodiment. Additionally, the appended claims should be construed to include other embodiments as well.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method for manufacturing a multi-junction solar cell, the method comprising:
forming a lower cell;
depositing a metal thin film layer on the lower cell;
heat-treating the metal thin film layer to form a recombination layer and an intermediate charge transport layer; and
forming an upper cell on the intermediate charge transport layer.

2. The method of claim 1, wherein the metal thin film layer contains one of Ti, Ni, and Mo.

3. The method of claim 2, wherein the lower cell is formed by sequentially depositing a lower electrode, a lower absorption layer, and an emitter layer,
wherein the lower absorption layer is a silicon substrate.

4. The method of claim 3, wherein the metal thin film layer contains one of Ni and Mo when the emitter layer is of an n-type,
wherein the metal thin film layer contains Ti when the emitter layer is of a p-type.

5. The method of claim 4, wherein the recombination layer formed by the heat-treatment of the metal thin film layer is made of one silicide among TiSi₂, NiSi₂, and MoSi₂.

6. The method of claim 4, wherein, in the heat-treating of the metal thin film layer, the intermediate charge transport layer formed by the heat-treatment of the metal thin film layer is made of one metal oxide among TiO₂, NiO₂, and MoO_{X}.

7. The method of claim 1, wherein the heat-treating of the metal thin film layer includes simultaneously forming the recombination layer and the intermediate charge transport layer via the heat-treatment in an oxygen atmosphere.

8. A multi-junction solar cell comprising:
a lower cell including a lower electrode, a lower absorption layer, and an emitter layer deposited sequentially;
a recombination layer disposed on the emitter layer;
an intermediate charge transport layer disposed on the recombination layer; and
an upper cell disposed on the intermediate charge transport layer and including an upper absorption layer and an upper electrode deposited sequentially.

9. The multi-junction solar cell of claim 8, wherein a metal thin film layer is deposited on the emitter layer and then heat-treated,
wherein metal atoms of the metal thin film layer diffuse into the emitter layer to form the recombination layer made of silicide,
wherein at a surface of the metal thin film layer, oxygen atoms diffuse into a metal thin film to form the intermediate charge transport layer made of metal oxide.

10. The multi-junction solar cell of claim 9, wherein the lower absorption layer includes a silicon substrate,
wherein the upper absorption layer contains perovskite.

11. The multi-junction solar cell of claim 10, wherein the heat-treatment is performed in an oxygen atmosphere, so that the recombination layer made of the silicide and the intermediate charge transport layer made of the metal oxide are formed simultaneously.
